(19) United States
(12) Patent Application Publication
(10) Pub. No.: US 2024/0372376 A1
(43) Pub. Date: Nov. 7, 2024

(54) Methods and Systems for Battery Authentication

(71) Applicant: Google LLC, Mountain View, CA (US)

(72) Inventors: David Wang, San Jose, CA (US); James Robert Lim, Mountain View, CA (US)

(73) Assignee: Google LLC, Mountain View, CA (US)

(21) Appl. No.: 18/651,359

(22) Filed: Apr. 30, 2024

Related U.S. Application Data
(60) Provisional application No. 63/499,895, filed on May 3, 2023.

(51) Int. Cl. H02J 7/00; G01R 31/367; G01R 31/371; H01M 10/42; H01M 50/574; H01M 50/584

(52) U.S. Cl. CPC H02J 7/00045; G01R 31/367; G01R 31/371; H01M 10/4221; H01M 10/425; H01M 50/574; H01M 50/584; H02J 7/007188; H01M 2010/4278

(57) ABSTRACT

The present document describes methods and systems for battery authentication. In aspects, the battery includes an identifier (ID) resistor integrated into the battery label and having at least one exposed resistor contact. The location of the resistor contact can be used for mechanical keying for identification of the battery. The ID resistor has a resistance value that corresponds to a type of the battery. To detect the ID resistor, a device can have electrical contacts (e.g., pogo pins) that are exposed in a battery housing and that electrically connect to the resistor contact(s) of the battery. The device can use a lookup table to identify the type of the battery based on the resistance value of the ID resistor. Such identification of the type of the battery enables authentication of the battery to the device and initiation of one or more functions based on whether the battery is valid.

### CROSS-REFERENCE TO RELATED APPLICATIONS

This application claims priority to U.S. Provisional Application Ser. No. 63/499,895, filed May 3, 2023, the disclosure of which is incorporated by reference herein in its entirety.

### BACKGROUND

Cylindrical cell batteries such as AAA batteries have standard dimensions and terminal locations that enable interchangeability between electronic devices. As the only interface between the battery and the device is the positive and negative terminals, there is no effective way to differentiate between different battery brands and/or models within the same format. Such lack of battery differentiation can be problematic due to an increasing number of battery chemistries introduced in the same format. For example, AAA batteries have traditionally been Alkaline (1.5 Volts (V) nominal, non-rechargeable, 860˜1200 milliampere hours (mAh) capacity range). However, different battery chemistries provide a variety of models with different voltages, capacities, and charge capabilities.

If a battery chemistry not intended for a particular device is used in that device, it can significantly impact device performance and/or damage the device. For example, a battery having a low nominal voltage can result in reduced runtime for the device or failure to power on the device. A battery having a high voltage can cause device damage by exceeding a maximum voltage rating of the device. A battery having a low capacity can result in reduced runtime (e.g., lower than expected) of the device. Different capacities can result in inaccurate fuel-gauge state-of-charge tracking of the battery. Further, charging a non-rechargeable battery or charging at a voltage exceeding a maximum specification for the battery can result in the battery overheating and, in some cases, rupturing, which can damage the device and potentially cause harm to a user. These issues result in a poor user experience and safety hazards. Such performance and safety issues cannot be completely prevented by simply providing written warning to the user via a product safety manual or safety label and relying on the user to know the difference between, for example, different types of AAA batteries.

### SUMMARY

The present document describes methods and systems for battery authentication. In aspects, the battery includes an identifier (ID) resistor integrated into the battery label and having at least one exposed resistor terminal. The location of the resistor terminal can be used for mechanical keying for identification of the battery. The ID resistor has a resistance value that corresponds to the type of battery (e.g., battery chemistry of the battery, nominal voltage of the battery, capacity of the battery). To detect the ID resistor, a device can have electrical contacts (e.g., pogo pins) that are exposed in a battery housing and that electrically connect to the resistor terminal(s) of the battery. The device can use a lookup table to identify the type of battery based on the resistance value. Such identification of the type of battery enables authentication of the battery to the device and initiation of one or more functions based on whether the battery is valid.

In aspects, a method for battery authentication is disclosed. The method includes detecting power from a battery assembled to an electronic device, the battery having a cell can and a label that covers at least a portion of a surface of the cell can. The label includes an ID resistor embedded in a middle layer of the label and at least one resistor contact exposed via the label. The method also includes determining a resistance value of the ID resistor embedded in the label of the battery. In addition, the method includes determining whether the battery is authenticated to the electronic device based on the resistance value. Also, the method includes initiating a first functionality of the electronic device if the battery is authenticated or a second functionality of the electronic device if the battery is not authenticated.

In aspects, a system is disclosed. The system includes one or more batteries and an electronic device. Each battery includes: (i) a cell can having a longitudinal axis that intersects positive and negative terminals at opposing ends of the cell can; (ii) a label disposed on an exterior surface of the cell can between the positive and negative terminals; and (iii) an ID resistor embedded within the label and having at least one resistor contact exposed via the label. In implementations, the ID resistor has a resistance value associated with a type of the battery. The electronic device includes a battery housing configured to receive the one or more batteries. The electronic device also includes at least one electrical contact disposed in the battery housing. The electrical contact is configured to directly connect to the at least one resistor contact of the ID resistor. The electronic device further includes an analog-to-digital converter electrically connected to the electrical contact. The analog-to-digital converter is configured to apply a voltage to the ID resistor to detect the resistance value. In addition, the electronic device includes a microcontroller configured to determine the resistance value of the ID resistor based on the voltage, determine the type of the battery on the resistance value, determine whether the battery is authenticated to the electronic device based on the type of the battery, and initiate a first functionality of the electronic device if the battery is authenticated or a second functionality of the electronic device if the battery is not authenticated.

This summary is provided to introduce simplified concepts of battery authentication, which are further described below in the Detailed Description. This summary is not intended to identify essential features of the claimed subject matter, nor is it intended for use in determining the scope of the claimed subject matter.

### BRIEF DESCRIPTION OF THE DRAWINGS

The details of one or more aspects of battery authentication are described in this document with reference to the following drawings. The same numbers are used throughout the drawings to reference like features and components:

FIG. 1 illustrates an example implementation of an electronic device configured for battery authentication in accordance with the techniques described herein;

FIG. 2 illustrates an example implementation of the electronic device from FIG. 1 in more detail;

FIG. 3 illustrates an example of a cylindrical cell standard-form-factor battery;

FIG. 4 illustrates an example layer stack of a label from FIG. 1 for a battery, in accordance with implementations described herein;

FIG. 5 illustrates example plan views of the outer layer, the middle layer, and the inner layer, respectively, of the label of the battery;

FIG. 6 illustrates an example implementation of the battery from FIG. 1;

FIG. 7 illustrates an example circuit diagram representing a system having batteries connected in parallel;

FIG. 8 illustrates another example circuit diagram representing a system having batteries connected in series;

FIG. 9 illustrates an example view of a portion of the electronic device from FIG. 1 having a battery housing for receiving cylindrical form factor batteries;

FIGS. 10A and 10B illustrate examples of resistor terminals exposed at different locations of the label;

FIGS. 11A and 11B illustrate examples of label stacks for a single resistor terminal of the ID resistor embedded in the label;

FIG. 12 illustrates example plan views of the outer layer, the middle layer, and the inner layer, respectively, of the label from FIGS. 11A and 11B;

FIG. 13 illustrates an example implementation of the battery from FIG. 1 for a single-cell configuration or cells connected in parallel sharing a common ground;

FIG. 14 illustrates an example circuit diagram representing a system having batteries connected in parallel and sharing a common ground;

FIG. 15 illustrates an example view of a portion of the electronic device from FIG. 1 having a battery housing for receiving cylindrical form factor batteries with a single resistor terminal for an ID resistor embedded in the label;

FIGS. 16A and 16B illustrate examples of resistor terminals exposed at different locations of the label for a single-cell configuration or parallel-connected cells sharing a common ground; and

FIG. 17 depicts an example method for battery authentication.

### DETAILED DESCRIPTION

Some custom battery packs include a battery identifier (ID) resistor placed on a battery printed circuit board (PCB), which is read by an electronic device's microcontroller unit (MCU) analog-to-digital converter (ADC) for battery authentication. However, such custom batteries generally have unique mechanical dimensions (e.g., size, shape) and unique connector keying to prevent any other battery from being installed in the device. Cylindrical cell standard-form-factor batteries have standard dimensions with only positive and negative terminals of the cell. Further, many cylindrical cell standard-form-factor batteries have different nominal voltages and capacities. There is currently no effective way for the device to verify if the cylindrical cell standard-form-factor battery (or batteries) installed have a safe and appropriate nominal voltage and capacity for the device.

The present document describes methods and systems for battery authentication. Cylindrical cell batteries generally include a label adhered to an exterior surface of the cell can. In implementations, an ID resistor is embedded within the label with at least one contact exposed via the exterior surface of the label. The exposed contact can interface with an electrical contact (e.g., pogo pin) in the battery housing of the device to complete a circuit. The device can then detect the resistance of the ID resistor and, based on the resistance and a lookup table, determine the type of battery, such as by determining a battery chemistry, nominal voltage, and/or capacity. Based on the determination of the battery chemistry, for example, the device can determine whether the battery is valid and safe for use in the device, if performance will be impacted, or if the battery is unsafe (e.g., potential of overheating) for use in the device.

The techniques described herein enable determination of battery capacity “Q,” voltage “V,” and a change in capacity versus a change in voltage “dQ/dV,” which in turn enables adjustment of a fuel gauge chemical ID for accurate tracking of battery state-of-charge. Also, when a non-valid battery chemistry or non-authenticated battery is used that may impact runtime or performance, the device can notify the user via, for example, an LED indicator, a haptic indicator, an audio indicator, another device (e.g., smartphone notification, app notification), and so forth. When a prohibited battery chemistry is identified in the device, the device can disable battery charging and/or device operation for safety. Accordingly, battery authentication of cylindrical cell standard-form-factor batteries improves the user experience, sentiment, and trust relative to the device. These techniques can be applied without additional bill of materials at the battery and without changing the standard dimensions of the battery, because the ID resistor is integrated into the battery label.

While features and concepts of the described techniques for battery authentication can be implemented in any number of different environments, aspects are described in the context of the following examples.

### Example Device

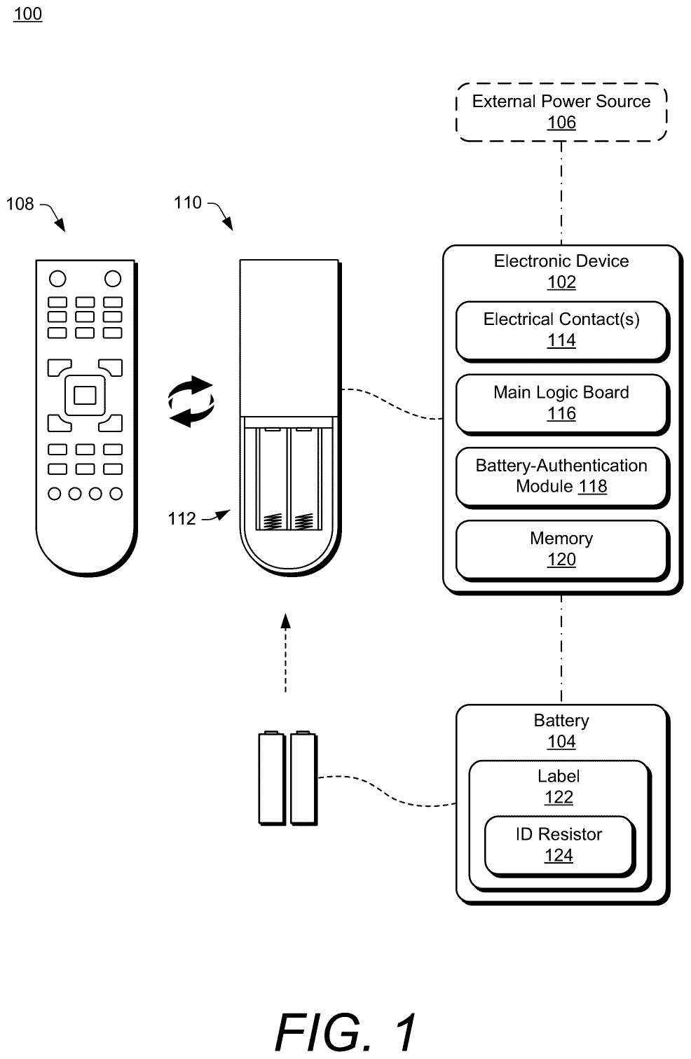

FIG. 1 illustrates an example implementation 100 of an electronic device 102 configured for battery authentication in accordance with the techniques described herein. The illustrated example includes the electronic device 102 and one or more batteries 104, which provide battery power to the electronic device 102. In some aspects, the electronic device 102 is also electrically connected to an external power source 106, which provides line power to the electronic device 102. In one example, the electronic device 102 can use the line power for some functions and use the battery power for one or more other functions. In this way, the battery-powered function can operate without interfering with a line-powered function. In some aspects, the coupling to the external power source 106 may be a wireless connection (e.g., using inductive coils). In FIG. 1, an example electronic device 102 is illustrated as a remote controller, shown in a front view 108 and a rear view 110. As illustrated, the remote controller includes a battery housing 112 for receiving one or more batteries 104. Within the battery housing 112 are electrical contacts 114 that electrically couple to one or more resistor terminals of resistors integrated into labels of the batteries 104.

The electronic device 102 includes a printed circuit board (e.g., main logic board (MLB) 116) configured to perform one or more functions, including executing a battery-authentication module 118. In implementations, the battery-authentication module 118 is configured to authenticate the battery 104 using information stored in a memory 120 (e.g., non-transitory media) of the electronic device 102. If the battery 104 is authenticated by the battery-authentication module 118, then normal function of the electronic device 102 can be enabled. However, if the battery 104 is not authenticated by the battery-authentication module 118, the battery-authentication module 118 can disable functionality of the electronic device 102 and, in some cases, alert a user that at least one invalid battery is being used and device performance is likely to be impacted.

The battery 104 can be any suitable standard-form-factor battery, including a standard-form-factor cylindrical cell battery. Some example batteries include AA, AAA, C, D, N, and so forth. The battery 104 can be a rechargeable battery or a non-rechargeable battery. Multiple batteries 104 can be connected in parallel or in series to provide power to the electronic device 102. Alternatively, multiple batteries 104 connected in series can be used to provide power to the electronic device 102. In implementations, the battery 104 includes a label 122 adhered to a cell can. Also, embedded within the label 122 is an ID resistor 124. The ID resistor 124 can include a resistance value corresponding to a battery chemistry of the battery 104. When the battery 104 is assembled to the electronic device 102, the electronic device 102 can detect the resistance value of the ID resistor 124 to authenticate the battery 104 and ensure that the correct type of battery chemistry (and voltage) is being used to power the electronic device 102.

The electronic device 102 may also be configured to communicate with one or more devices or servers over a network (e.g., wireless network). By way of example and not limitation, the electronic device 102 may communicate data over a local-area-network (LAN), a wireless local-area-network (WLAN), a personal-area-network (PAN), a wide-area-network (WAN), an intranet, the Internet, a peer-to-peer network, point-to-point network, or a mesh network.

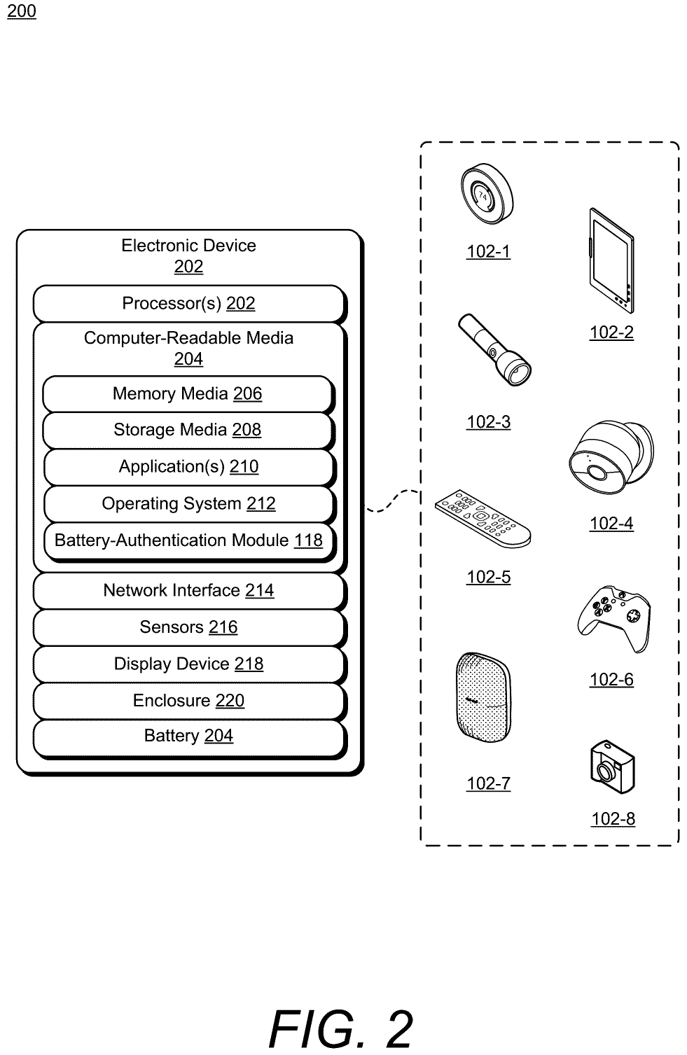

Consider now FIG. 2, which illustrates an example implementation of the electronic device from FIG. 1 in more detail. The electronic device 102 of FIG. 2 is illustrated with a variety of example devices, including a smart thermostat 102-1, an e-reader 102-2, a flashlight 102-3, a security camera 102-4, a remote controller 102-5, a gaming controller 102-6, a speaker 102-7, and a camera 102-8. The electronic device 102 can include any suitable battery-powered device, including battery-powered toys for children.

The electronic device 102 includes one or more processors 202 (e.g., any of microprocessors, controllers, or other controllers) that can process various computer-executable instructions to control the operation of the electronic device 102 and to enable techniques for battery authentication. Alternatively or additionally, the processor(s) 202 can be implemented with any one or combination of hardware elements, firmware, or fixed logic circuitry that is implemented in connection with processing and control circuits. Although not shown, the electronic device 102 can include a system bus or data transfer system that couples the various components within the device. A system bus can include any one or combination of different bus structures, such as a memory bus or memory controller, a peripheral bus, a universal serial bus, and/or a processor or local bus that utilizes any of a variety of bus architectures.

The electronic device 102 can also include computer-readable media 204 (CRM 204). The CRM 204 includes memory media 206 and storage media 208. The CRM 204 may include one or more memory devices (e.g., the storage media 208) that enable persistent and/or non-transitory data storage (in contrast to mere signal transmission), examples of which include random access memory (RAM), non-volatile memory (e.g., any one or more of a read-only memory (ROM), flash memory, erasable programmable read-only memory (EPROM), electrically erasable programmable read-only memory (EEPROM), etc.), and a disk storage device. A disk storage device may be implemented as any type of magnetic or optical storage device, such as a hard disk drive, a recordable and/or rewritable compact disc (CD), any type of a digital versatile disc (DVD).

Applications 210 and/or an operating system 212 implemented as computer-readable instructions on the computer-readable media 204 (e.g., the storage media 208) can be executed by the processor(s) 202 to provide some or all of the functionalities described herein. The computer-readable media 204 provides data storage mechanisms to store various device applications 210, an operating system 212, memory/storage, and other types of information and/or data related to operational aspects of the electronic device 102. For example, the operating system 212 can be maintained as a computer application within the computer-readable media 204 and executed by the processor(s) 202 to provide some or all of the functionalities described herein. The device applications 210 may include a device manager, such as any form of a control application, software application, or signal-processing and control modules. The device applications 210 may also include system components, engines, or managers to implement techniques for battery authentication, such as the battery-authentication module 118. The electronic device 102 may also include, or have access to, one or more machine learning systems.

Various implementations of the battery-authentication module 118 can include, or communicate with, a System-on-Chip (SoC), one or more Integrated Circuits (ICs), a processor with embedded processor instructions or configured to access processor instructions stored in memory, hardware with embedded firmware, a printed circuit board with various hardware components, or any combination thereof.

The electronic device 102 may also include a network interface 214. The electronic device 102 can use the network interface 214 for communicating data over wired, wireless, or optical networks. By way of example and not limitation, the network interface 214 may communicate data over a local-area-network (LAN), a wireless local-area-network (WLAN), a personal-area-network (PAN), a wide-area-network (WAN), an intranet, the Internet, a peer-to-peer network, point-to-point network, or a mesh network. The network interface 214 can be implemented as one or more of a serial and/or parallel interface, a wireless interface, any type of network interface, a modem, or any other type of communication interface. Using the network interface 214, the electronic device 102 may communicate via a cloud computing service to access a platform having resources.

The electronic device 102 also includes one or more sensors 216, which can include any of a variety of sensors, including an audio sensor (e.g., a microphone), a touch-input sensor (e.g., a touchscreen, a fingerprint sensor, a capacitive touch sensor), an image-capture device (e.g., a camera or video camera), a proximity sensor (e.g., capacitive sensor), a motion-detection sensor (e.g., passive infrared sensor), a temperature sensor (e.g., thermistor), or an ambient light sensor (e.g., photodetector).

The electronic device 102 can also include a display device (e.g., display device 218). The display device 218 can include any suitable touch-sensitive display device, e.g., a touchscreen, a liquid crystal display (LCD), thin film transistor (TFT) LCD, an in-place switching (IPS) LCD, a capacitive touchscreen display, an organic light-emitting diode (OLED) display, an active-matrix organic light-emitting diode (AMOLED) display, super AMOLED display, and so forth. The display device 218 may be referred to as a display or a screen, such that digital content may be displayed on-screen.

The electronic device 102 can also include an enclosure 220. The enclosure 220 houses the components of the electronic device 102. The enclosure 220 can form or include a battery housing to receive and secure one or more batteries 104 used to provide power to the electronic device 102. The enclosure 220 can also include a cover that mechanically connects (e.g., snaps) to a body of the enclosure to cover the battery housing and any batteries 104 assembled therein.

The battery 104, as mentioned, can be any suitable standard-form-factor battery, including a cylindrical cell battery. The battery 104 can include any suitable chemistry, some examples of which include zinc carbon, alkaline, lithium ion, nickel-metal hydride (NiMH), nickel cadmium (NiCd), and so forth. Different battery chemistries have different operating characteristics, such as discharge profiles, self-discharge rate, voltage levels, and capacities. Further, some battery chemistries enable recharging of the battery and other battery chemistries are non-rechargeable.

The battery 104 includes an ID resistor (e.g., ID resistor 124 in FIG. 1) usable by the electronic device 102 to authenticate the battery 104 to the electronic device 102. In aspects, the ID resistor 124 corresponds to a particular battery chemistry (e.g., via a lookup table stored in the storage media 208). Accordingly, by detecting the resistance of the ID resistor 124 on the battery 104, the electronic device 102 can authenticate whether the battery 104 is valid for use by the electronic device 102. Further details of this and other features are described below. In some implementations, the ID resistor 124 can be a variable resistor that changes based on temperature. For example, the ID resistor 124 can be a negative temperature coefficient (NTC) thermistor or a positive temperature coefficient (PTC) thermistor. Accordingly, the ID resistor 124 can provide an indication of a temperature associated with the battery 104. Determining the battery temperature can be critical for safety reasons because some battery chemistries, such as Li-ion batteries recently introduced in cylindrical standard-form-factor, output higher power and thus dissipate more heat than the more common battery chemistries like alkaline batteries.

Although not shown, the electronic device 102 also includes I/O interfaces for receiving and providing data. For example, the I/O interfaces may include one or more of a touch-sensitive input, a capacitive button, a microphone, a keyboard, a mouse, an accelerometer, a display, a light-emitting diode (LED) indicator, a speaker, or a haptic feedback device.

These and other capabilities and configurations, as well as ways in which entities of FIGS. 1 and 2 act and interact, are set forth in greater detail below. These entities may be further divided, combined, and so on. The implementation 100 of FIG. 1 and the detailed illustrations of FIG. 2 through FIG. 17 illustrate some of many possible environments, devices, and methods capable of employing the described techniques, whether individually or in combination with one another.

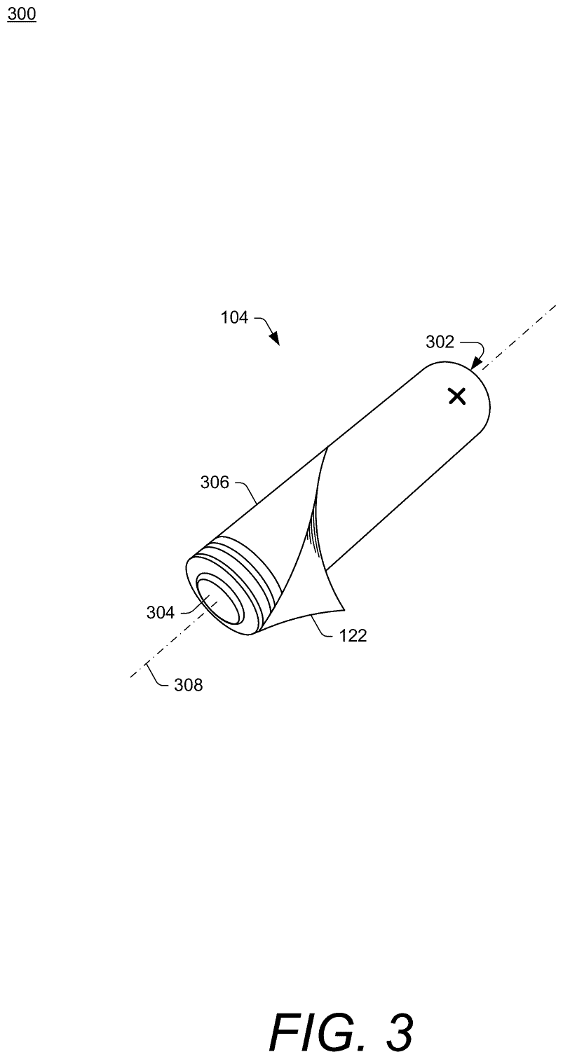

FIG. 3 illustrates an example 300 of a cylindrical cell standard-form-factor battery (e.g., the battery 104). In the example illustration, the battery 104 includes a positive terminal 302 (e.g., positive pole) and a negative terminal 304 (e.g., negative pole) at opposing ends of an elongated body (e.g., cell can 306) and intersected by a longitudinal axis 308. Generally, an exterior lateral surface (e.g., surface curving around the longitudinal axis 308) of the cell can 306 has positive polarity and is covered by the label 122. The label 122 provides a protective layer around the cell can 306 in addition to providing written information to the user.

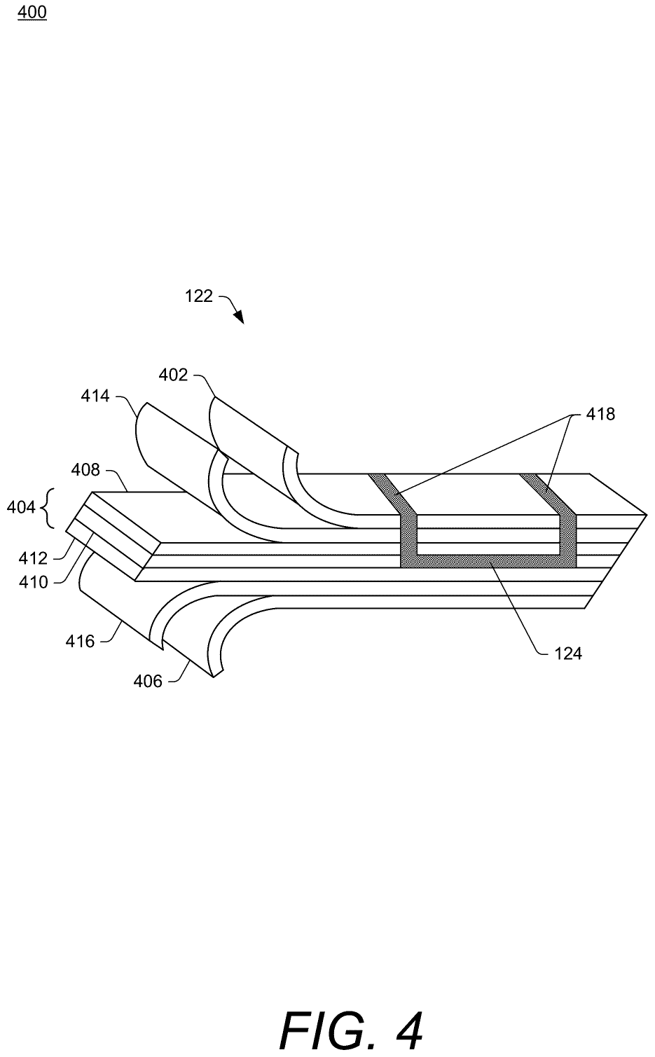

FIG. 4 illustrates an example layer stack 400 of the label 122 from FIG. 1 for a battery, in accordance with implementations described herein. The label 122 includes multiple layers, as illustrated. For example, the label 122 includes an outer layer 402, one or more middle layers 404, and an inner layer 406. The outer layer 402 provides a protective finish to the label 122 and may be a polyethylene terephthalate (PET) film. The inner layer 406 is an adhesive, such as pressure sensitive adhesive (PSA), which binds the label 122 to the cell can (e.g., cell can 306 in FIG. 3). The middle layer(s) 404 can include an ink layer 408 that provides color, graphical design, and written text for the label 122. The middle layer(s) 404 can also include a structural layer 410 (e.g., an aluminum coating), which provides some mechanical structure for the label 122, particularly during label manufacturing. The middle layer(s) 404 can also include a PET transparent film 412 to provide an abrasive surface for adhesive. The label 122 can also include an adhesive layer 414 that binds the outer layer 402 to the middle layer 404. The label 122 can also include an adhesive layer 416 that binds the middle layer 404 to the inner layer 406. In aspects, the inner layer 406 may be a PET film.

The ID resistor 124 is embedded in the middle layer(s) 404 and connected to one or more resistor contacts 418 (e.g., Nickel (Ni) contact) that are exposed via the exterior surface (e.g., the outer layer 402) of the label 122. The resistor contacts 418 are terminals for the ID resistor 124. Further, the resistor contacts 418 can be any suitable shape and size, including strips, dots, triangles, rectangles, etc. In one example, the ID resistor 124 is integrated in the ink layer 408. In another example, the ID resistor 124 is integrated in the structural layer 410. In yet another example, the ID resistor 124 can form an additional layer adjacent to the structural layer 410 (e.g., between the structural layer 410 and the ink layer 408). The structural layer 410 may have its own resistance, which can be combined with the resistance of the ID resistor 124 to a predefined value that corresponds to the desired ID resistance for identification of the battery 104. In an example, the ID resistor 124 is a graphite strip. However, the ID resistor 124 can be any suitable material that can act as a resistor.

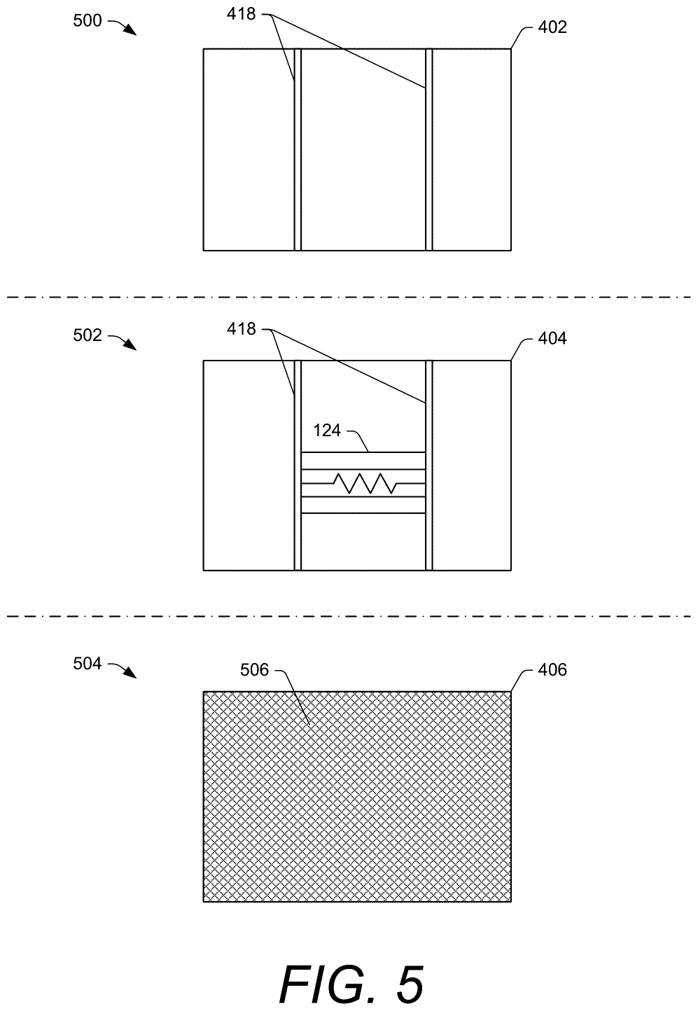

FIG. 5 illustrates example plan views 500, 502, and 504 of the outer layer 402, the middle layer 404, and the inner layer 406, respectively, of the label 122 of the battery 104. In the example illustrated in view 500, the outer layer 402 includes two resistor contacts 418 (e.g., Ni contact strips) exposed via the exterior surface of the outer layer 402. In the example illustrated in view 502, the middle layer 404 includes the two resistor contacts 418, extending down from the outer layer 402 and interconnecting the ID resistor 124. As mentioned, the ID resistor 124 may be a graphite material acting as a resistor. In the example illustrated in view 504, the inner layer 406 includes a PSA 506. In this example, the resistor contacts 418 do not extend into the inner layer 406.

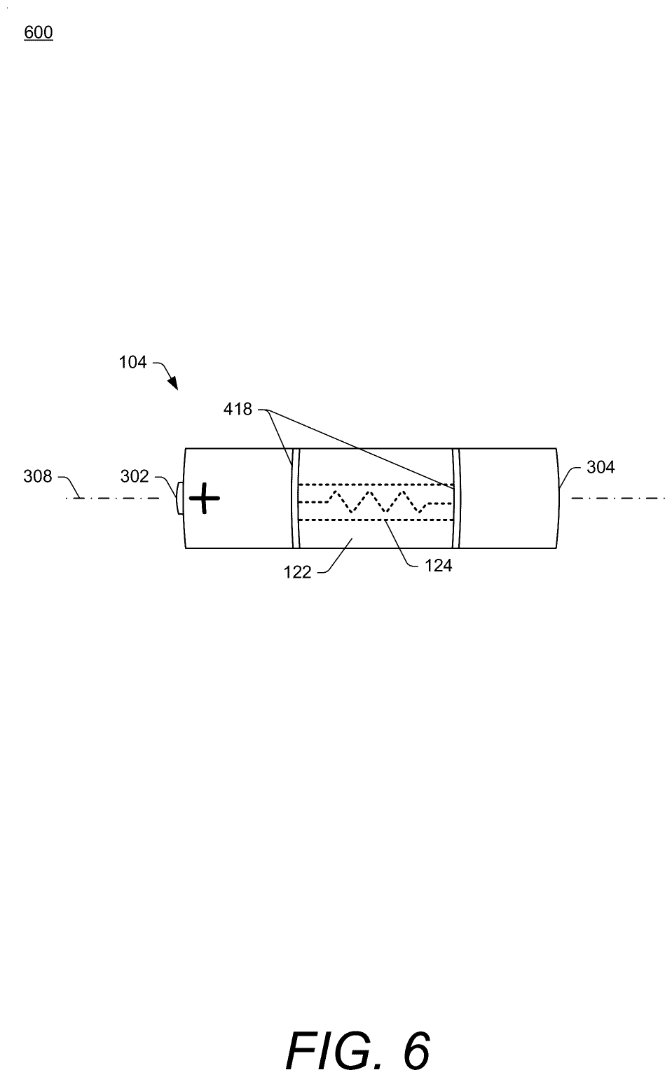

FIG. 6 illustrates an example implementation 600 of the battery 104 from FIG. 1. As illustrated, the battery 104 includes the resistor contacts 418 (e.g., resistor terminals) between the positive terminal 302 and the negative terminal 304 of the battery 104. The resistor contacts 418 interconnect the ID resistor 124 integrated into the label 122. The resistor contacts 418 are exposed via the label 122 on the lateral sides (e.g., sides substantially parallel to the longitudinal axis 308). In some implementations, the resistor contacts 418 are strips that are exposed all the way around the longitudinal axis 308 (e.g., around the circumference of the battery 104). In other implementations, the resistor contacts 418 are exposed only partially around the longitudinal axis 308 of the battery 104 or exposed at multiple locations distributed around the longitudinal axis 308 of the battery 104.

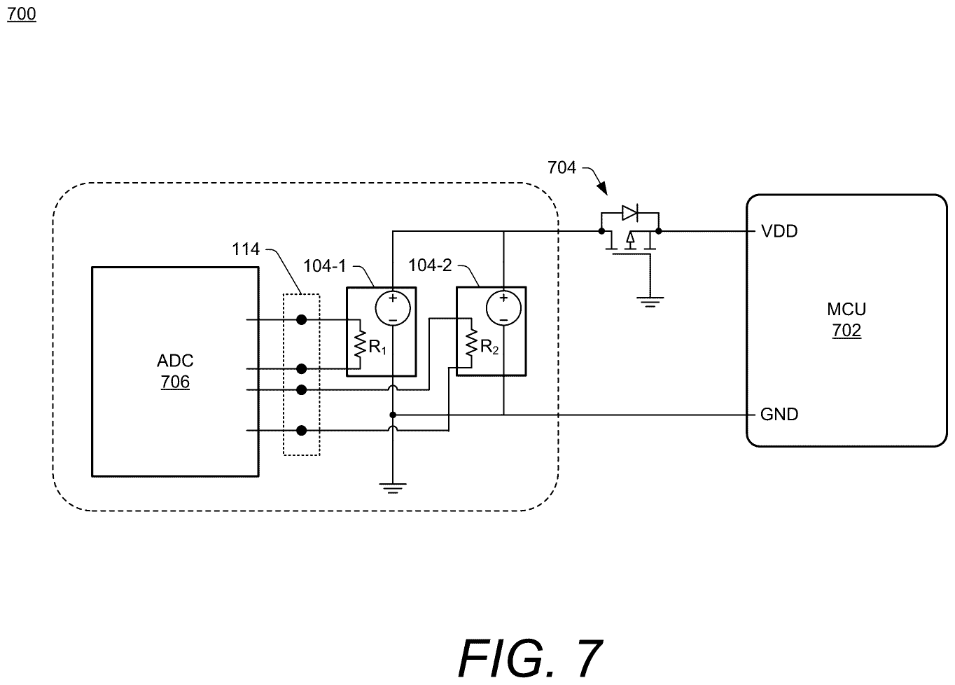

FIG. 7 illustrates an example circuit diagram 700 representing a system having batteries connected in parallel. On the right side of the diagram 700 is a microcontroller unit (MCU) 702 of the electronic device 102 and at least one transistor 704. In aspects, the MCU 702 executes the battery-authentication module 118 to perform one or more functions to authenticate the battery 104. On the left side of the diagram 700 is an ADC 706 that connects to each of the batteries 104 (e.g., a first battery 104-1 and a second battery 104-2). In the illustrated example, the ADC 706 connects to each terminal of each of the two batteries 104. For example, the first battery 104-1 includes a first ID resistor R₁ embedded in its label, as described above, and the second battery 104-2 includes a second ID resistor R₂ embedded in its label. Each terminal of the first ID resistor R₁ (e.g., each exposed resistor contact 418 from FIG. 6) is electrically connected to the ADC 706 via an electrical contact 114 (e.g., pogo pin), represented by black dots, that interfaces with that terminal to complete the circuit. Similarly, each terminal of the second ID resistor R₂ is electrically connected to the ADC 706 via an electrical contact (e.g., pogo pin) that interfaces with that terminal to complete the circuit. Although the diagram 700 includes four electrical contacts 114 (e.g., two contacts for each battery 104), additional electrical contacts can be implemented to accommodate additional batteries (e.g., a pair of electrical contacts for the ID resistor 124 of each battery 104). In addition, each of the batteries 104-1 and 104-2 are parallel-connected to a ground node of the MCU 702.

In this way, the ADC 706 can detect the resistance associated with the ID resistor of each battery. For example, the ADC 706 can apply a current to obtain a voltage reading. Using the voltage reading, the MCU 702 can determine the battery identity or the battery chemistry, such as by comparing the voltage reading or the resistance value to a lookup table.

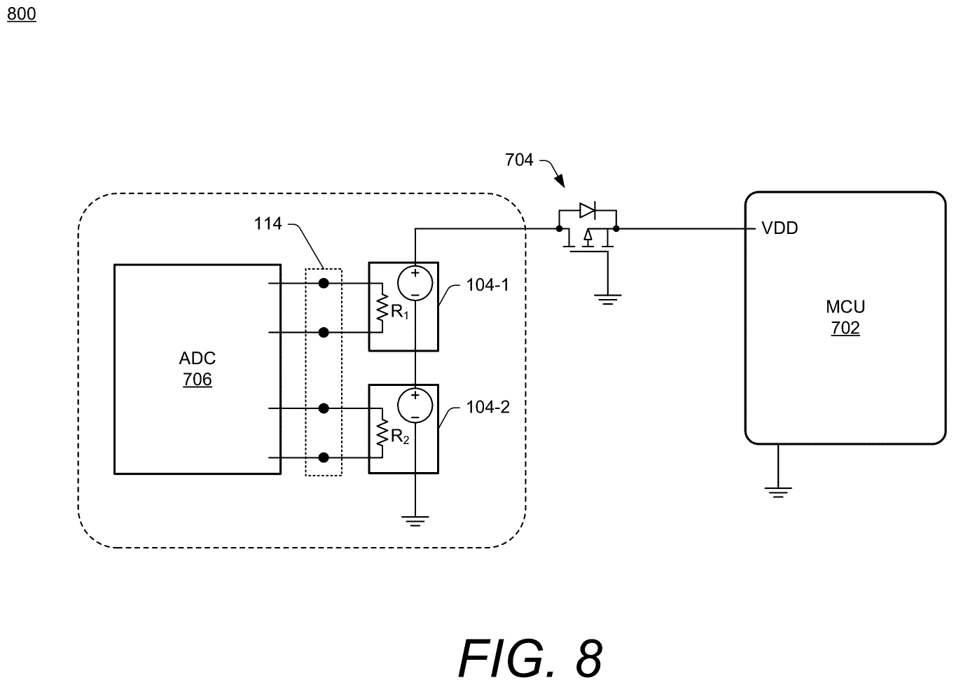

FIG. 8 illustrates another example circuit diagram 800 representing a system having batteries connected in series. In this example, the batteries 104-1 and 104-2 are series connected to the MCU 702. Similar to the previous example, both resistor terminals of the first ID resistor R₁ of the first battery 104-1 are connected to the ADC 706 via the electrical contacts 114 (e.g., pogo pins) that interface with the resistor terminals exposed via the label of the first battery 104-1. In addition, both resistor terminals of the second ID resistor R₂ of the second battery 104-2 are connected to the ADC 706 via the electrical contacts 114 that interface with the resistor terminals exposed via the label of the second battery 104-2. Although the diagram 800 includes four electrical contacts 114 (e.g., two contacts for the ID resistor 124 of each battery 104), additional electrical contacts can be implemented to accommodate additional batteries (e.g., a pair of electrical contacts for each battery 104).

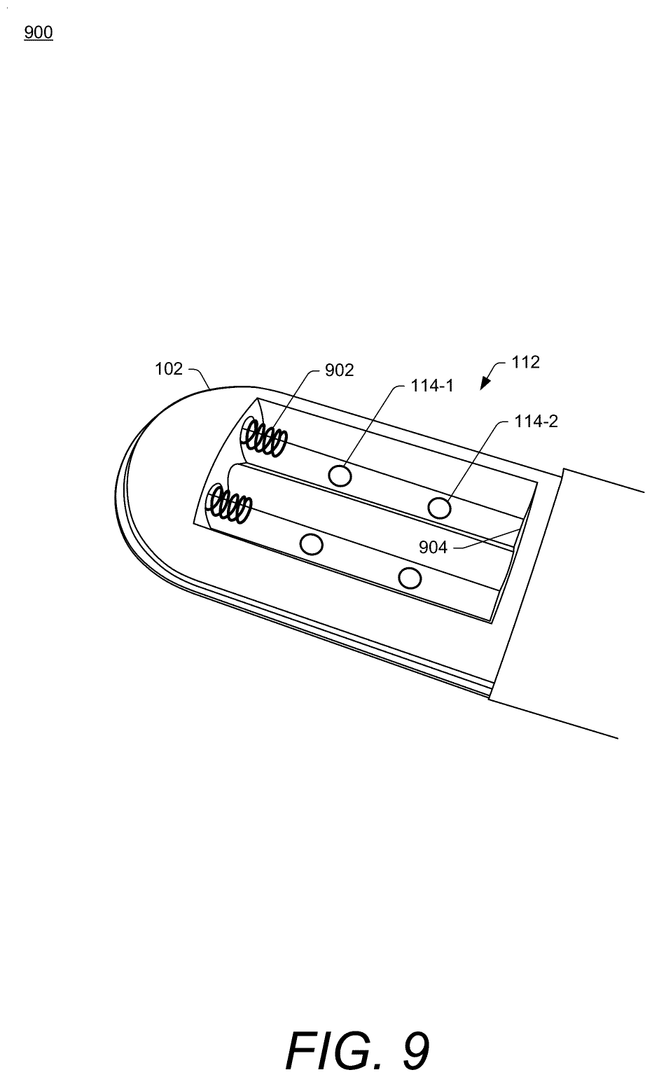

FIG. 9 illustrates an example view 900 of a portion of the electronic device from FIG. 1 having a battery housing for receiving cylindrical cell form-factor batteries. In the illustrated example, the electronic device 102 includes the battery housing 112 to receive and secure two batteries 104. The battery housing includes, for each battery, a negative contact 902 and a positive contact 904. The battery housing 112 includes exposed electrical contacts (e.g., the electrical contacts 114, which are configured to interface with the resistor contacts exposed on the lateral side of each battery (e.g., battery 104 from FIG. 6) assembled to the battery housing 112. For example, contact 114-1 may be a negative contact and contact 114-2 may be a positive contact. The electrical contacts 114 may be any suitable conductive component, including, for example, pogo pins or springs that can extend outwardly from a surface of the battery housing 112 to interface with the exterior surface of the battery 104 when the battery 104 is located within the battery housing 112. Because the battery 104 is a cylindrical cell standard-form-factor battery, the battery 104 does not have any space to integrate a spring contact. Therefore, the spring contact is located in the battery housing 112 and, as described herein, the battery 104 includes the resistor terminals, which are resistor terminals of the ID resistor embedded in the label of the battery 104. In some implementations, the battery housing 112 can include multiple negative contacts 114-1 and/or multiple positive contacts 114-2 to enable authentication of different valid batteries having resistor contacts 418 in different locations (e.g., to differentiate between rechargeable batteries from rechargeable batteries having similar nominal voltages).

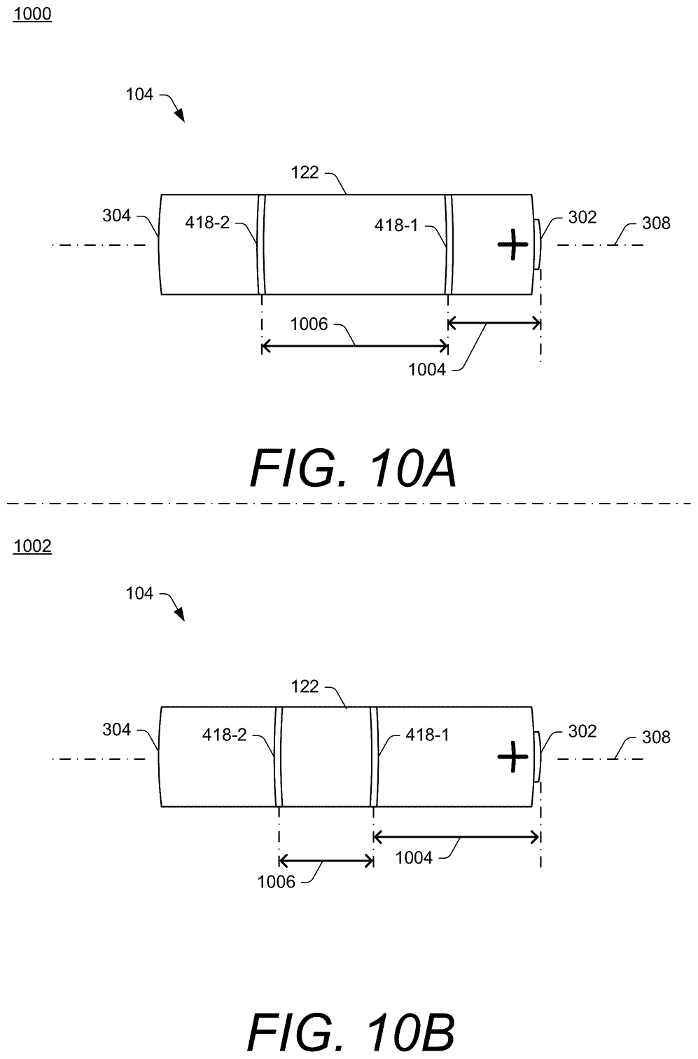

FIGS. 10A and 10B illustrate examples 1000 and 1002, respectively, of resistor terminals exposed at different locations of the label. The resistor terminals (e.g., resistor contacts 418) can be exposed at predefined locations relative to the positive terminal 302 or the negative terminal 304 of the battery 104. For example, a first resistor contact 418-1 can be located at a predefined distance 1004 from the positive terminal 302 (e.g., from a contact surface of the positive terminal 302). The predefined distance 1004 can be any suitable length, such as a length on the order of millimeters (e.g., 1 mm, 2 mm, 5 mm, 10 mm, 20 mm). In some implementations, the predefined distance 1004 can correspond (or be mapped to) a particular battery chemistry to enable the device to authenticate the battery 104. In one example, the predefined distance 1004 to the first resistor contact 418-1 in example 1000 in FIG. 10A is 10 mm, whereas the predefined distance 1004 to the first resistor contact 418-1 in example 1002 in FIG. 10B is 20 mm.

When assembled to the electronic device 102, the first resistor contact 418-1 (and the second resistor contact 418-2) may or may not align with the electrical contacts 114 of the electronic device 102 (described with respect to FIG. 9). If the resistor contacts 418 align and interface with the electrical contacts 114 in the battery housing 112 of the electronic device 102, then a circuit is completed to enable the electronic device 102 to detect the resistance of the ID resistor to potentially authenticate the battery 104. If one or both resistor contacts 418 do not align and interface with the electrical contacts 114 in the battery housing 112, then the circuit remains open and the electronic device 102 cannot detect the ID resistor and thus cannot authenticate the battery 104. In such a case, the electronic device 102 can determine that the battery 104 is not valid. Accordingly, the location of one or both resistor contacts 418 relative to the positive terminal 302 or the negative terminal 304 of the battery 104 can be used as mechanical keying at least as an initial check on whether the battery 104 is potentially a valid battery 104 for the electronic device 102.

In addition, a distance 1006 between the resistor contacts 418 can be used to define the resistance value of the ID resistor 124 embedded in the label 122. For example, the distance 1006 can be greater for higher resistance or shorter for lower resistance. Accordingly, the distance 1006 between the resistor contacts 418 as well as the predefined distance 1004 between one of the resistor terminals and the positive terminal 302 or the negative terminal 304 of the battery can both be used to define an identity of the battery 104 as it relates to the battery chemistry, brand, capacity, nominal voltage, etc. If the resistor contacts 418 align with the electrical contacts 114 in the battery housing 112 of the electronic device 102 to complete the circuit, it may be assumed that the battery 104 is valid for the electronic device 102. In some implementations, the electronic device 102 can perform an additional check on the battery 104 by detecting the resistance value of the ID resistor 124 and identifying the battery chemistry, capacity, and/or nominal voltage (e.g. based on a lookup table) to determine if device performance is likely to be impacted. In some implementations, unique relative locations of the resistor terminal(s) (e.g., distances 1004 and/or 1006) on the label 122 can be keyed to whether the battery 104 is rechargeable or non-rechargeable.

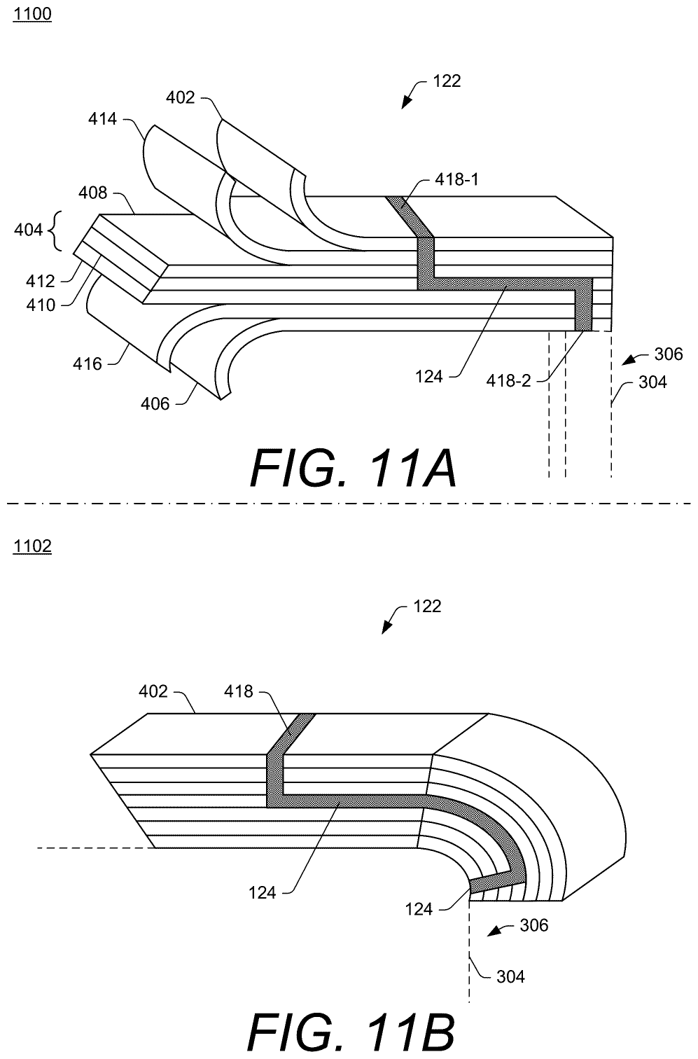

FIGS. 11A and 11B illustrate examples 1100 and 1102, respectively, of label stacks for a single resistor terminal of the ID resistor embedded in the label. For a single cell configuration or cells connected in parallel, a common ground can be used. By using a common ground, a single resistor terminal (e.g., resistor contact 418-1) can be exposed via the outer layer 402 of the label 122. In some aspects, the exposed resistor terminal (e.g., resistor contact 418-1) is a positive terminal of the ID resistor 124. The opposing resistor terminal (e.g., resistor contact 418-2) is a negative terminal of the ID resistor 124 extends through the inner layer 406. In aspects, the resistor contact 418-2 can connect directly to the negative terminal 304 of the battery 104 (represented by dashed lines) via the inner layer 406 of the label 122. In some implementations (e.g., example 1100 in FIG. 11A), the negative terminal (e.g., resistor contact 418-2) of the ID resistor 124 directly connects to a lateral side of the negative terminal 304 of the battery 104 (e.g., portion of the cell can having negative polarity). In other implementations (e.g., example 1102 in FIG. 11B), the label wraps around an edge of the cell can 306 to overlap a planar surface of the negative terminal 304 of the battery 104 that intersects the longitudinal axis (e.g., longitudinal axis 308 in FIG. 3) of the battery 104. As such, the resistor contact 418-2 of the ID resistor 124 directly connects to the planar surface of the negative terminal 304 of the battery 104.

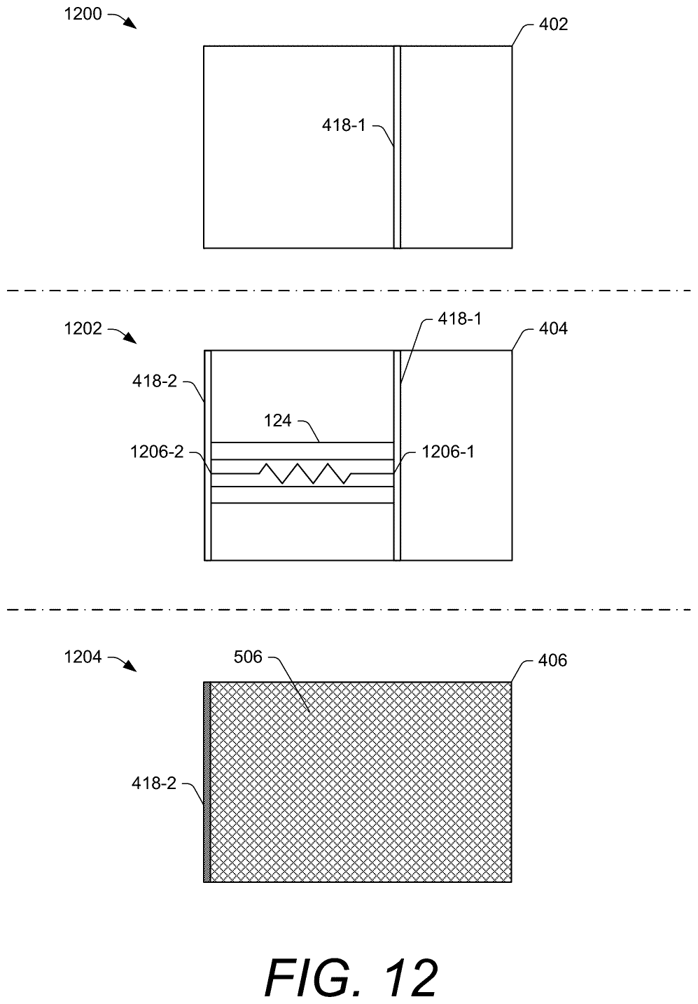

Continuing with the example of a single-cell configuration or cells connected in parallel sharing a common ground, FIG. 12 illustrates example plan views 1200, 1202, and 1204 of the outer layer 402, the middle layer 404, and the inner layer 406, respectively, of the label 122 of the battery 104. In the example illustrated in view 1200, the outer layer 402 includes a single resistor contact (e.g., resistor contact 418-1, Ni contact strip) exposed via the outer layer 402. In the example illustrated in view 1202, the middle layer 404 includes the ID resistor 124 having (i) a first end 1206-1 connected to the resistor contact 418-1 that extends up through the outer layer 402 and (ii) a second end 1206-2 connected to the other resistor contact (e.g., resistor contact 418-2), which extends from the middle layer 404 down through the inner layer 406. In the example illustrated in view 1204, the inner layer 406 includes the PSA 506 and the resistor contact 418-2, which can include conductive PSA to electrically connect the ID resistor 124 to a portion of the cell can 306 (common ground) having negative polarity.

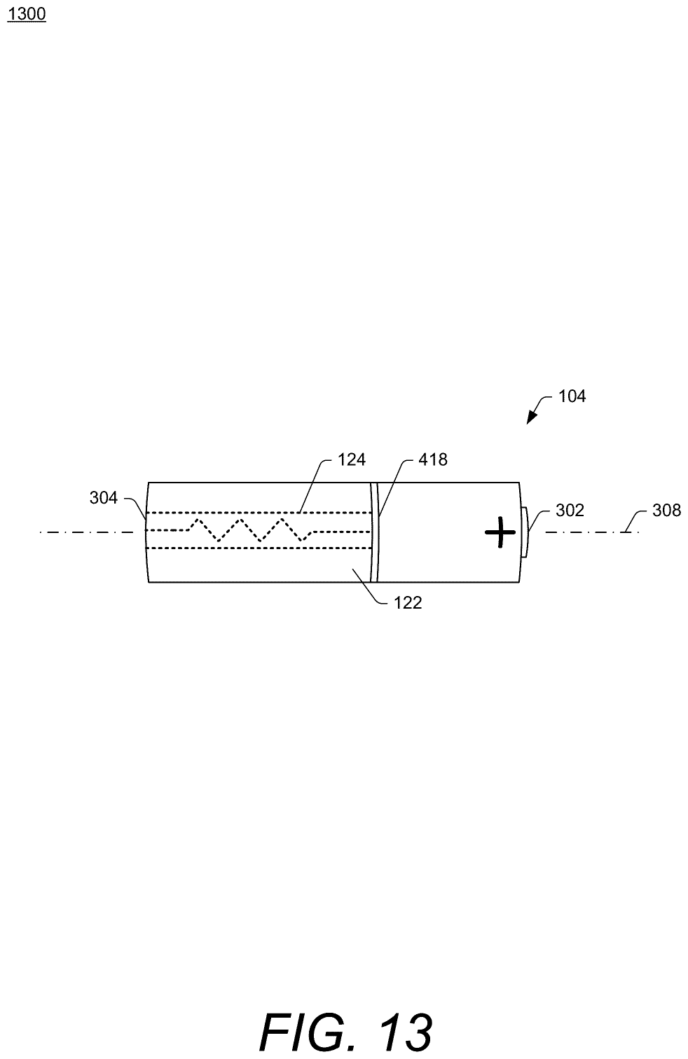

FIG. 13 illustrates an example implementation 1300 of the battery 104 from FIG. 1 for a single-cell configuration or cells connected in parallel sharing a common ground. As illustrated, the battery 104 includes a single resistor contact 418 (e.g., acting as a resistor terminal) exposed via the outer layer of the label 122. The resistor contact 418 is connected to the ID resistor 124, which is embedded within the label 122 and which extends along the longitudinal axis 308 of the battery 104 toward the negative terminal 304 of the battery 104. Through the inner layer (e.g., conductive PSA) of the label 122, the ID resistor 124 electrically connects to the negative terminal 304 of the battery 104.

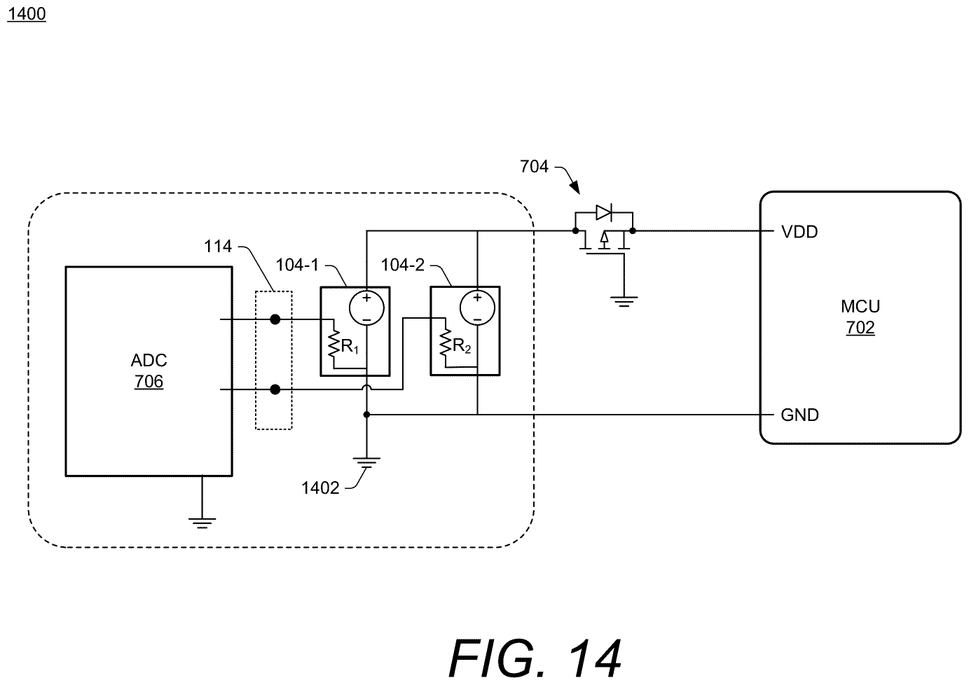

FIG. 14 illustrates an example circuit diagram 1400 representing a system having batteries connected in parallel and sharing a common ground. In this example, the batteries 104-1 and 104-2 are parallel-connected to the MCU 702 and share a common ground (e.g., ground 1402) with the MCU 702. Because the batteries 104 share a common ground, the ID resistors 124 can also share a common ground, thereby reducing the number of electrical contacts 114 used by the electronic device 102. For example, each ID resistor 124 has only one resistor terminal exposed for connection with the electrical contact 114 of the electronic device 102. The other resistor terminal directly connected to the negative terminal of the battery 104. Thus, in this example, the electronic device 102 only needs to use a single electrical contact 114 to connect to the ID resistor 124 of the battery 104. Accordingly, common-ground configuration can reduce the bill of materials (BOM) associated with implementing these techniques in devices (e.g., only one pogo pin and resistor terminal per cell) and reduce corresponding manufacturing costs.

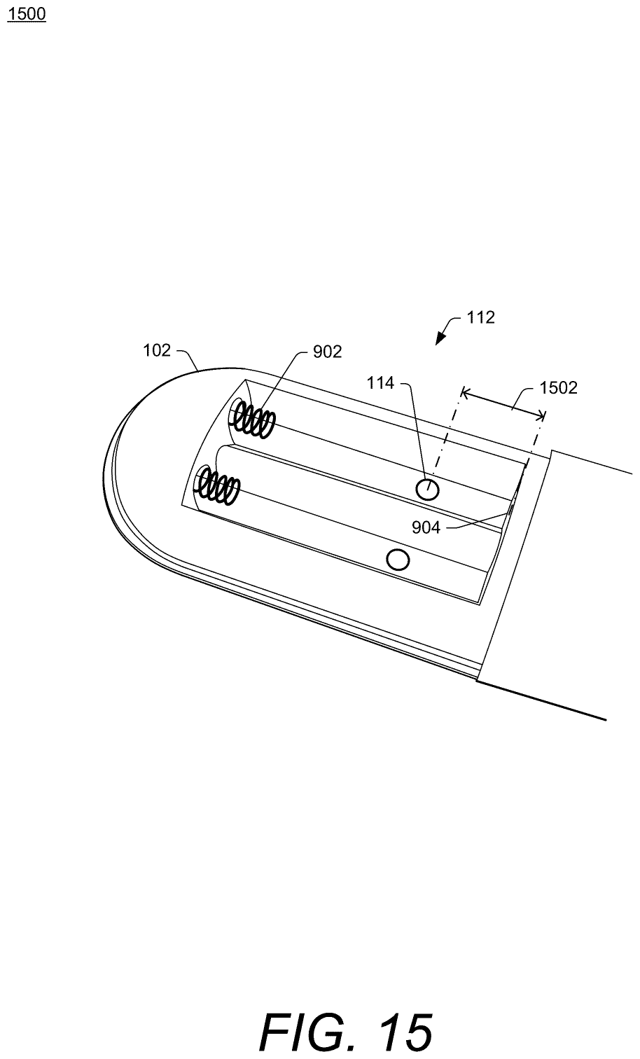

FIG. 15 illustrates an example view 1500 of a portion of the electronic device from FIG. 1 having a battery housing for receiving cylindrical form factor batteries with a single resistor terminal for an ID resistor embedded in the label. Here, the battery housing includes a single electrical contact 114 (e.g., pogo pin) for each battery 104 to be assembled therein. In this example, the electrical contact 114 is a positive contact because, as described above, the negative terminal of the ID resistor 124 is connected directly to the negative terminal of the battery.

As mentioned, the distance between the positive terminal of battery and the exposed resistor contact can be associated with the battery chemistry. Accordingly, the electrical contact 114 can be disposed at a predefined distance 1502 from the positive contact 904 in the battery housing such that the predefined distance 1502 aligns only with a battery having a matching distance between its exposed resistor contact and positive terminal. If a battery having an exposed resistor contact at a greater or lesser distance from its positive terminal is installed in the battery housing 112, the electronic device 102 cannot detect the ID resistor 124 and consequently can determine that the battery is not valid for the electronic device 102. In some implementations, the battery housing 112 can have multiple electrical contacts 114 that are positive contacts to enable mechanical keying for different valid batteries having resistor contacts in different locations, such as rechargeable versus non-rechargeable batteries that have similar nominal voltages.

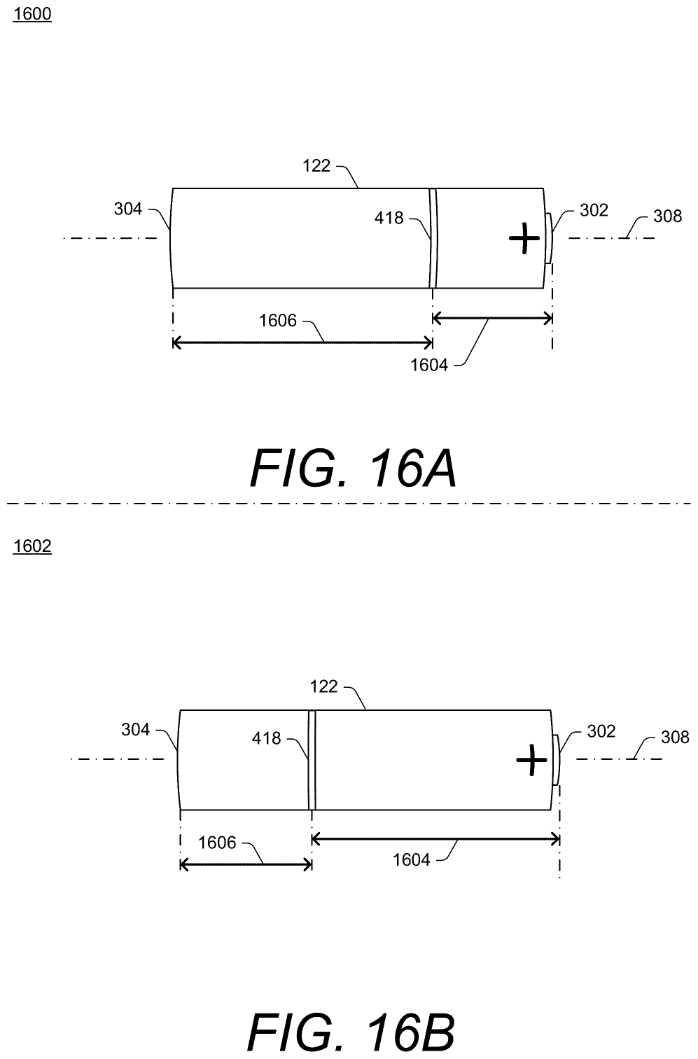

FIGS. 16A and 16B illustrate examples 1600 and 1602, respectively, of resistor contacts exposed at different locations of the label for a single-cell configuration or parallel-connected cells sharing a common ground. Similar to the implementation described with respect to FIGS. 10A and 10B, the single resistor terminal (e.g., resistor contact 418) can be exposed at a predefined location relative to the positive terminal 302 or the negative terminal 304 of the battery 104. For example, the resistor contact 418 can be located at a predefined distance 1604 from the positive terminal 302 of the battery 104. The predefined distance 1604 can be any suitable length (e.g., 1 mm, 2 mm, 5 mm, 10 mm, 20 mm). A distance 1606 between the resistor contact 418 and the negative terminal 304 of the battery 104, in this configuration, impacts the resistance of the ID resistor embedded in the label 122. Accordingly, the predefined distance 1604 and/or the distance 1606 can be used to authenticate the battery 104 using the techniques described herein.

### Example Methods

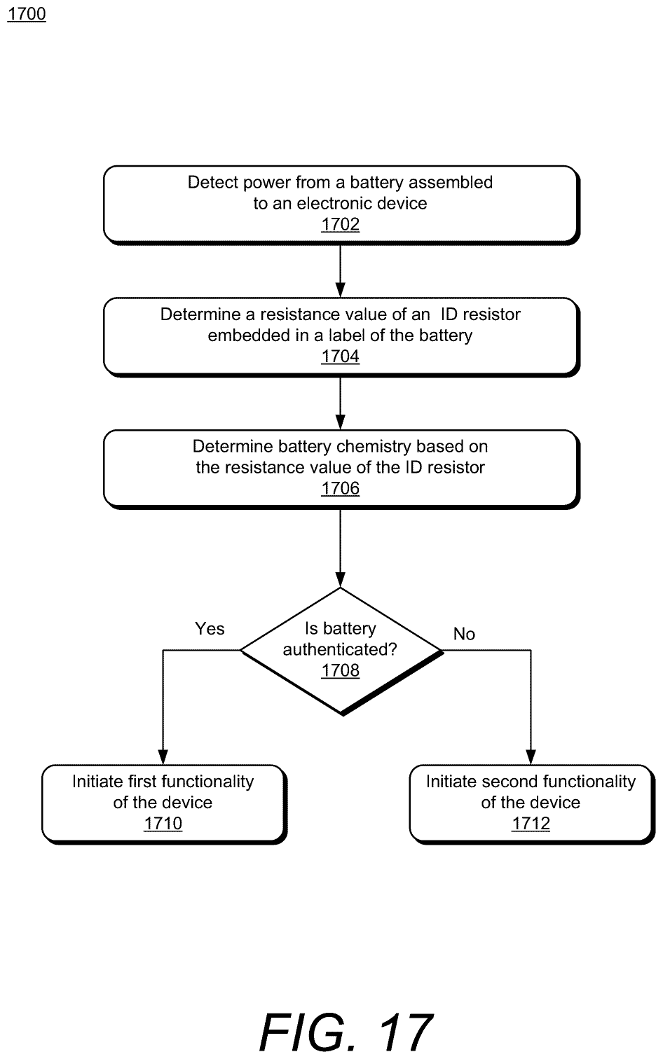

FIG. 17 depicts an example method 1700 for battery authentication. The method 1700 can be performed by the electronic device 102, which uses the MCU 702 to implement the described techniques. The method 1700 is shown as a set of blocks that specify operations performed but are not necessarily limited to the order or combinations shown for performing the operations by the respective blocks. Further, any of one or more of the operations may be repeated, combined, reorganized, or linked to provide a wide array of additional and/or alternate methods. In portions of the following discussion, reference may be made to the example implementation 100 of FIG. 1 or to entities or processes as detailed in FIGS. 2-16, reference to which is made for example only. The techniques are not limited to performance by one entity or multiple entities operating on one device.

At 1702, power is detected from a battery assembled to an electronic device. For example, when the battery 104 (or batteries) is assembled to the electronic device 102 and the electronic device 102 is turned on, the battery 104 provides power to at least the MLB 116 of the electronic device 102. The MCU 702 of the MLB 116 can detect power coming from the battery 104. In aspects, the MCU 702 pauses initialization of normal device operation to first authenticate the battery 104.

At 1704, a resistance value of an ID resistor embedded in the label of the battery is determined. For example, the ADC 706 of the electronic device 102 can provide a current to the ID resistor 124, read an associated voltage, and determine the resistance value of the ID resistor 124. As described herein, the ADC 706 is electrically connected to the ID resistor 124 via one or more electrical contacts 114 (e.g., pogo pins) in the battery housing 112 of the electronic device 102 and one or more resistor contacts 418 exposed via the label 122 of the battery 104.

At 1706, a battery chemistry of the battery is determined based on the resistance value of the ID resistor. For example, the MCU 702 of the electronic device 102 uses the resistance value or the voltage of the ID resistor 124 that was obtained by the ADC 706 and compares the resistance value or the voltage to a lookup table. The MCU 702 uses the lookup table to convert the resistance value or the voltage to the type of chemistry (e.g., battery chemistry) of the battery 104. Optionally, a temperature associated with the battery is determined based on the resistance value of the ID resistor. For example, if the ID resistor 124 is a variable resistor that changes resistance based on changes in temperature, then the resistance value can be used to determine the battery temperature.

At 1708, the electronic device determines if the battery is authenticated (e.g., valid) based on the battery chemistry. For example, the MCU 702 determines if the identified battery chemistry matches specifications for the device. If the battery chemistry matches the device specifications, then the battery is authenticated. If, however, the battery chemistry does not match, then the battery is not authenticated. In another example, the MCU 702 uses the battery chemistry to determine a nominal voltage and a capacity of the battery 104. The MCU 702 can then determine whether the nominal voltage is within an appropriate voltage range for safely powering the electronic device 102 and whether the capacity is sufficient to power the electronic device 102 for an expected runtime according to normal device operation. If the nominal voltage is too high, then the battery is not safe to use in the electronic device 102. If the voltage or capacity is low, device operation and runtime may be significantly impacted. If, for example, the battery 104 is not present or if the electrical contact 114 of the electronic device 102 does not connect with the resistor contact 418, then the ADC 706 reads (at 1704) a significantly high resistance, and consequently, the MCU 702 determines (at 1706) the battery chemistry based on that high resistance and determines (at 1708) that the battery chemistry is not valid for use with the electronic device 102 or that device runtime will be significantly impacted. Optionally, the temperature associated with the battery can be used as an initial check on battery authentication. For example, if the resistance value is within a predefined resistance range, then the MCU 702 can determine that the temperature of the battery 104 is within a safe temperature range.

If the battery is authenticated (“YES” at 1708), then at 1710, a first functionality of the electronic device is initiated. For example, if the battery chemistry of the battery indicates that the battery 104 is an appropriate battery to use in the electronic device 102, then the MCU 702 can enable normal device operation. In some implementations, the MCU 702 can enable a battery-charging function and set a correct charging voltage based on the determined battery chemistry. In some implementations, the MCU 702 can use the determined battery chemistry to adjust a fuel gauge battery chemical ID to correct a capacity associated with the battery 104 and a capacity-to-voltage lookup table associated with the battery 104.

If the battery is not authenticated (“NO” at 1708), then at 1712, a second functionality of the electronic device is initiated. For example, if the battery is not authenticated, then the MCU 702 can disable battery charging. In another example, the second functionality includes disabling normal operation of the electronic device 102. In some implementations, the MCU 702 can adjust the fuel gauge chemical ID associated with the battery 104 to a correct capacity-to-voltage lookup table specific for the determined battery chemistry. The second functionality can also include providing a notification to the user to warn the user of the invalid battery and/or of a potential performance impact. In some cases, the electronic device 102 can also provide a recommendation, to the user, of a correct type of battery to use in the electronic device 102.

### CONCLUSION

Although aspects of cylindrical cell standard-form-factor battery authentication have been described in language specific to features and/or methods, the subject of the appended claims is not necessarily limited to the specific features or methods described. Rather, the specific features and methods are disclosed as example implementations of the techniques for cylindrical cell standard-form-factor battery authentication, and other equivalent features and methods are intended to be within the scope of the appended claims. Further, various aspects are described, and it is to be appreciated that each described aspect can be implemented independently or in connection with one or more other described aspects.

What is claimed is:

1. A method for battery authentication, the method comprising:
detecting power from a battery assembled to an electronic device, the battery having a cell can and a label that covers at least a portion of a surface of the cell can, the label including an identifier (ID) resistor embedded in a middle layer of the label and at least one resistor contact exposed via the label;
determining a resistance value of the ID resistor embedded in the label of the battery;
determining whether the battery is authenticated to the electronic device based on the resistance value; and
initiating a first functionality of the electronic device if the battery is authenticated or a second functionality of the electronic device if the battery is not authenticated.

2. The method of claim 1, wherein initiating the first functionality of the electronic device includes enabling battery charging and setting a correct charging voltage based on the resistance value.

3. The method of claim 1, wherein initiating the first functionality of the electronic device includes adjusting a fuel gauge battery chemical ID to correct a capacity and a capacity-to-voltage lookup table associated with the battery.

4. The method of claim 1, wherein initiating the first functionality of the electronic device includes enabling normal device operation.

5. The method of claim 1, wherein initiating the second functionality of the electronic device includes disabling battery charging.

6. The method of claim 1, wherein initiating the second functionality of the electronic device includes disabling normal operation of the electronic device.

7. The method of claim 1, wherein initiating the second functionality of the electronic device includes adjusting a fuel gauge battery chemical ID to correct a capacity associated with the battery or a capacity-to-voltage lookup table associated with the battery based on the resistance value.

8. The method of claim 1, wherein initiating the second functionality of the electronic device includes providing at least one of a notification to a user of the electronic device that the battery is not valid or a notification to the user that device performance may be impacted by using the battery in the electronic device.

9. The method of claim 8, wherein the notification indicates that runtime of the electronic device may be impacted by using the battery.

10. The method of claim 8, wherein the notification is communicated to another device associated with the user via a wireless network.

11. The method of claim 1, wherein determining the resistance value of the ID resistor embedded in the label of the battery is based on an electrical connection between an analog-to-digital converter in the electronic device and the at least one resistor contact exposed via the label.

12. The method of claim 11, wherein the electrical connection is facilitated by an electrical contact in a battery housing of the electronic device that directly connects to the at least one resistor contact exposed via the label.

13. The method of claim 1, further comprising determining a type of the battery based on the resistance value by using a lookup table to convert the resistance value or a voltage associated with the resistance value to the type of the battery.

14. The method of claim 13, wherein the determining the type of the battery includes determining at least one of a nominal voltage, a capacity, or a rechargeability of the battery based on the type of the battery.

15. A system comprising:
one or more batteries, each battery comprising:
a cell can having a longitudinal axis that intersects positive and negative terminals at opposing ends of the cell can;
a label disposed on an exterior surface of the cell can between the positive and negative terminals; and
an identifier (ID) resistor embedded within the label and having at least one resistor contact exposed via the label, the ID resistor having a resistance value associated with a type of the battery; and
an electronic device comprising:
a battery housing configured to receive the one or more batteries;
at least one electrical contact disposed in the battery housing, the at least one electrical contact configured to directly connect to the at least one resistor contact of the ID resistor;
an analog-to-digital converter electrically connected to the at least one electrical contact, the analog-to-digital converter configured to apply a voltage to the ID resistor to detect the resistance value; and
a microcontroller configured to:
determine the resistance value of the ID resistor based on the voltage;
determine the type of the battery on the resistance value;
determine whether the battery is authenticated to the electronic device based on the type of the battery; and
initiate a first functionality of the electronic device if the battery is authenticated or a second functionality of the electronic device if the battery is not authenticated.

16. The system of claim 15, wherein the first functionality of the electronic device that is initiated by the microcontroller includes one of:
initiation of battery charging and setting a correct charging voltage based on the resistance value;
adjustment of a fuel gauge battery chemical ID to correct a capacity and a capacity-to-voltage lookup table associated with the battery; or
enablement of normal device operation.

17. The system of claim 15, wherein the microcontroller is configured to initiate the second functionality of the electronic device by at least one of:
disabling battery charging;
disabling normal operation of the electronic device;
adjusting a fuel gauge battery chemical ID to correct a capacity associated with the battery or a capacity-to-voltage lookup table associated with the battery based on the resistance value; or
providing at least one of a notification to a user of the electronic device that the battery is not valid or a notification to the user that device performance may be impacted by using the battery in the electronic device.

18. The system of claim 17, wherein:
the notification indicates that runtime of the electronic device may be impacted by using the battery; and
the notification is communicated to another device associated with the user via a wireless network.

19. The system of claim 15, wherein the microcontroller is configured to determine the type of the battery based on the resistance value by using a lookup table to convert the resistance value or a voltage associated with the resistance value to the type of the battery.

20. The system of claim 19, wherein microcontroller is further configured to determine at least one of a nominal voltage, a capacity, or a rechargeability of the battery based on the type of the battery.
